(19) United States
(12) Patent Application Publication
(10) Pub. No.: US 2010/0139761 A1
(43) Pub. Date: Jun. 10, 2010

(54) DYE-SENSITIZED SOLAR CELL AND METHOD OF FABRICATING THE SAME

(75) Inventors: Hogyeong Yun, Seoul (KR); Yongseok Jun, Daejeon (KR); Mangu Kang, Daejeon (KR); Hunkyun Pak, Daejeon (KR); Jongdae Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/546,608

(22) Filed: Aug. 24, 2009

(30) Foreign Application Priority Data
Dec. 8, 2008 (KR) 10-2008-124070
Apr. 8, 2009 (KR) 10-2009-0030264

(51) Int. Cl. H01L 31/00; H01L 31/18

(52) U.S. Cl. 136/256; 438/69; 257/E27.123; 257/E31.11

(57) ABSTRACT

Provided are a dye-sensitized solar cell and a method of fabricating the same. The dye-sensitized solar cell includes a lower substrate, an upper substrate, a dielectric, a semiconductor electrode layer, a dye layer, and an electrolyte. The upper substrate is spaced from the lower substrate and has a light emitting surface facing a surface of the lower substrate and a light incident surface opposite to the light emitting surface. The dielectric is disposed on the surface of the lower substrate. The semiconductor electrode layer includes electrode dots disposed on the dielectric. The dye layer is disposed on surfaces of the electrode dots. The electrolyte is disposed between the lower substrate and the upper substrate.

### CROSS-REFERENCE TO RELATED APPLICATIONS

This U.S. non-provisional patent application claims priority under 35 U.S.C. §119 of Korean Patent Application No. 10-2008-00124070, filed on Dec. 8, 2008, and 10-2009-0030264, filed on Apr. 8, 2009, the entire contents of which are hereby incorporated by reference.

### BACKGROUND OF THE INVENTION

The present invention disclosed herein relates to a solar cell and a method of fabricating the same, and more particularly, to a dye-sensitized solar cell and a method of fabricating the same.

Solar cells are photovoltaic energy conversion systems that convert light energy radiated from the sun into electrical energy. Silicon solar cells, which are mainly used at present, employ a p-n junction diode formed in silicon for photovoltaic energy conversion. However, to prevent premature recombination of electrons and holes, the silicon should have a high degree of purity and less defects. Since these technical requirements cause an increase in material cost, silicon solar cells have a high fabrication cost per watt.

Moreover, since only photons, which have an energy level greater than a bandgap, contribute to generating current, silicon used for silicon solar cells is doped to have a lower bandgap. However, due to the lowered bandgap, electrons excited by blue light or ultraviolet light become overly energized and are consumed to generate heat rather than electrical current. Also, a p-type layer should be sufficiently thick to increase photon capturing probability. However, since the thick p-type layer increases the probability of excited electrons recombining with holes before they reach a p-n junction, the efficiency of silicon solar cells remains low in an approximate range of about 7% to about 15%.

In 1991, Michael Gratzel, Mohammad K. Nazeeruddin, and Brian O'Regan disclosed a Dye-sensitized Solar Cell (DSC), based on the photosynthesis reaction principle, and known as the “Gratzel cell” in U.S. Pat. Nos. 4,927,721 and 5,350,644, which are hereby incorporated by reference in their entirety. A dye-sensitized solar cell, which employs the Gratzel model as a prototype, is a photoelectrochemical system that employs a dye material and a transition metal oxide layer instead of a p-n junction diode for photovoltaic energy conversion. Since the material used in such a dye-sensitized solar cell is inexpensive and the fabrication method is simple, fabrication costs of the dye-sensitized solar cells are lower than those of silicon solar cells. Furthermore, since a dye-sensitized solar cell has an energy conversion efficiency similar to that of the silicon solar cell, it has a lower fabrication cost per output watt than the silicon solar cell. Accordingly, if technologies capable of increasing the energy conversion efficiency and output energy are developed, the dye-sensitized solar cells will be commercialized at once.

### SUMMARY OF THE INVENTION

The present invention provides a dye-sensitized solar cell capable of providing increased energy conversion efficiency and a method of fabricating the same.

The present invention also provides a dye-sensitized solar cell capable of increasing its useful life and a method of fabricating the same.

Embodiments of the present invention provide dye-sensitized solar cells including: a lower substrate; an upper substrate spaced from the lower substrate, the upper substrate having a light emitting surface facing a surface of the lower substrate and a light incident surface opposite to the light emitting surface; a dielectric disposed on the surface of the lower substrate; a semiconductor electrode layer including electrode dots disposed on the dielectric; a dye layer disposed on surfaces of the electrode dots; and an electrolyte disposed between the lower substrate and the upper substrate.

In some embodiments, the dielectric may include a silicon oxide layer or be formed of a ceramic or polymer material.

In other embodiments, the lower and upper substrates may be flexible.

In still other embodiments, the lower substrate may include one of a polymer layer coated with a conductive material or a metal layer.

In even other embodiments, the upper substrate may include a transparent polymer layer.

In yet other embodiments, dye-sensitized solar cells may further include: a catalyst layer disposed on the light emitting surface of the upper substrate; and a conductive layer disposed between the catalyst layer and the light emitting surface.

In further embodiments, the lower substrate may be formed of at least one of metals and metal alloys or may include a glass or a polymer layer coated with a conductive material.

In other embodiments of the present invention, methods of fabricating a dye-sensitized solar cell include: forming a dielectric on a lower substrate; forming a semiconductor electrode layer including electrode dots on the dielectric; absorbing a dye layer on surfaces of the electrode dots; disposing an upper substrate on the semiconductor electrode layer; and injecting an electrolyte between the lower substrate and the upper substrate.

In some embodiments, the dielectric may be formed using one of a spin-coating, a dip-coating, a chemical vapour deposition, a physical vapour deposition, and an atomic layer chemical vapor deposition.

In other embodiments, the methods may further include performing a thermal process after the dielectric is formed.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view of a dye-sensitized solar cell according to an embodiment of the present invention;

FIG. 2 is a sectional view of a dye-sensitized solar cell according to another embodiment of the preset invention;

FIGS. 3A and 3B are sectional views illustrating a method of fabricating a dye-sensitized solar cell according to an embodiment of the present invention; and

FIG. 4 is a sectional view illustrating a method of fabricating a dye-sensitized solar cell according to another embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Since preferred embodiments are provided below, the order of the reference numerals given in the description is not limited thereto. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. The word ‘and/or’ means that one or more or a combination of relevant constituent elements is possible.

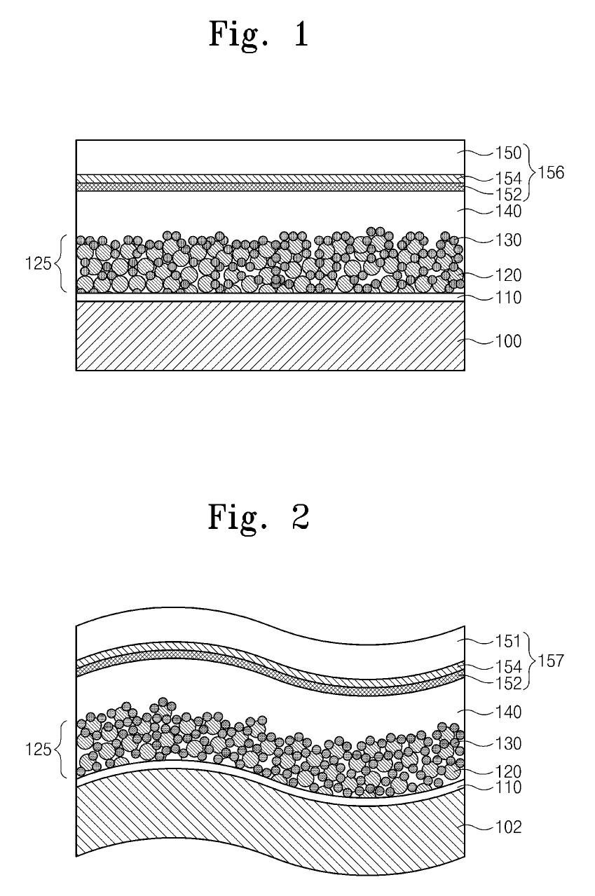

FIG. 1 is a sectional view of a dye-sensitized solar cell according to an embodiment of the present invention.

Referring to FIG. 1, a lower substrate 100 is prepared. An upper substrate 150 spaced from the lower substrate 100 may be disposed. The upper substrate 150 may have a light emitting surface facing a surface of the lower substrate 100 and a light incident surface opposite to the light emitting surface. A dielectric 110 may be disposed on the surface of the lower substrate 100. Thus, the dielectric 110 may be disposed between the lower substrate 100 and the upper substrate 150. A semiconductor electrode layer 125 including electrode dots 120 may be disposed on the dielectric 110. Dye layer 130 may be disposed on surfaces of the electrode dots 120. An electrolyte 140 may be disposed between the lower substrate 100 and the upper substrate 150. As described above, since the dielectric 110 is disposed on the surface of the lower substrate 100, the electrolyte 140 may be disposed between the dielectric 110 and the upper substrate 150.

The lower substrate 100 may be formed of a conductive material. For example, the lower substrate 100 may be formed of at least one of metals and metal alloys. The whole lower substrate 100 may be formed of the conductive material. Alternatively, the lower substrate 100 may include a glass or a polymer layer coated with the conductive material.

The dielectric 110 may include a silicon oxide layer or be formed of a ceramic or polymer material. Since the dielectric 110 is disposed on the surface of the lower substrate 100, the lower substrate 100 may be separated from the electrolyte 140. Thus, energy conversion efficiency and useful life of the dye-sensitized solar cell may increase.

When the electrolyte 140 contacts the lower substrate 100, the electrolyte 140 may corrode the lower substrate 100. A degree of the corrosion may increase as time goes by. When the lower substrate 100 is corroded by the electrolyte 140, the amount of electrons, which are excited in the dye layer 130 by irradiated sunlight, transferred to the lower substrate 100 may decrease. As a result, as the degree of the corrosion increases, the energy conversion efficiency of the dye-sensitized solar cell may decrease to reduce the useful life thereof.

However, according to an embodiment of the present invention, since the lower substrate 100 is separated from the electrolyte 140 by the dielectric 110, the dielectric 110 may minimizes a phenomenon in which the lower substrate 100 is corroded by the electrolyte 140. Thus, since the corrosion of the lower substrate 100 is minimized, the dye-sensitized solar cell having increased useful life may be provided.

Furthermore, since the lower substrate 100 may be separated from the electrolyte 140, the premature recombination(a portion of the excited electrons do not take part in a working process, and injected into the electrolyte 140 in a process in which the electrons excited in the dye layer 130 by the irradiated sunlight are transferred to the lower substrate 100) may be minimized Thus, the number of electrons taking part in the working process may increase, and the dye-sensitized solar cell having the increased energy conversion efficiency and output energy may be provided.

The dielectric 110 may have a thickness at which the corrosion of the lower substrate 100 may be minimized Also, the dielectric 100 may have a thickness at which the electrons excited in the dye layer 130 by the irradiated sunlight tunnel into the dielectric 110, and thus, are easily transferred into the lower substrate 100. For example, the dielectric 110 may have a thickness in the range of several nanometers to several hundred manometers.

The semiconductor electrode layer 125 may include the electrode dots 120. The electrode dots 120 may be formed of one of various metal oxides containing transition metal oxide. For example, the electrode dots 120 may be formed of one of titanium oxide (TiO₂), tin oxide (SnO₂), zirconium oxide (ZrO₂), magnesium oxide (MgO), neobium oxide (Nb₂O₅), and zinc oxide (ZnO).

The dye layer 130 may include dye molecules that can convert light energy into electrical energy. A ruthenium complex may be used as a dye material. For example, the dye material may include N719 (Ru(dcbpy)2(NCS)2 containing 2 protons). Alternatively, at least one of various well-known dye materials such as N712, Z907, Z910, and K19 may be used for fabricating the dye-sensitized solar cell according to the present invention.

The electrolyte 140 may include a redox iodide electrolyte. For example, the electrolyte 140 may include an electrolyte of I₃⁻/I⁻ obtained by dissolving 0.7 M 1-vinyl-3-hexyl-imidazolium iodide, 0.1 M LiI, and 40 mM I₂(Iodine) in 3-methoxypropionitrile. On the other hand, the electrolyte 140 may include an acetonitrile electrolyte containing 0.6 M butylmethylimidazolium, 0.02 M I₂, 0.1 M guanidinium thiocyanate, and 0.5 M 4-tert-butylpyridine. However, one of various electrolytes not exemplarily mentioned above may be used as the electrolyte for dye-sensitized solar cell according to the present invention. For example, the electrolyte 140 may include alkylimidazolium iodides or tetra-alkyl ammoniumiodides. The electrolyte 140 may further include tert-butylpyridin (TBP), benzimidazole (BI), and N-Methylbenzimidazole (NMBI) as surface additives, and may use acetonitrile, propionitrile, or a mixed liquid of acetonitrile and valeronitrile as a solvent.

A catalytic layer 152 may be disposed on the light emitting surface of the upper substrate 150. A conductive layer 154 may be disposed between the catalytic layer 152 and the light emitting surface. Thus, the conductive layer 154 and the catalytic layer 152 may be sequentially disposed on the light emitting surface of the upper substrate 150. The upper substrate 150, the conductive layer 154, and the catalytic layer 152 may constitute an upper substrate structure 156.

The upper substrate 150 may include a glass substrate. The conductive layer 154 may be formed of at least one of tin oxide (ITO), fluorine doped tin oxide (FTO), antimony tin oxide (ΛTO), SnO₂, ZnO, and carbon nanotubes. The catalytic layer 152 may be include a platinum (Pt) layer, which is coated on the conductive layer 154 with the amount of about 5-10 μg/cm². The catalytic layer 152 may contact the electrolyte 140. Thus, the catalytic layer 152 may inject the returned electrons, which takes part in the working process, into the electrolyte 140 to reduce the electrolyte 140. For example, when the electrolyte 140 contains a triiodide compound, the catalytic layer 152 may reduce the triiodide compound to an iodide compound.

An interconnection structure (not shown) connecting the lower substrate 100 to the conductive layer 154 may be disposed. The interconnection structure may include a predetermined load, and the load may consume energies of the electrons.

Sunlight may incident onto the light incident surface of the upper substrate 150. The sunlight may pass through the inside of the upper substrate 150 and be emitted from the light emitting surface of the upper substrate 150 to the conductive layer 154, the catalytic layer 152, the electrolyte 140, and the dye layer 130. The electrons within the dye layer 130 may be excited by the sunlight irradiated into the dye layer 130. The excited electrons may be transferred to the lower substrate 100 through the semiconductor electrode layer 125 including the electrode dots 120. In this process, the electrons may tunnel into the dielectric 110. The electrons transferred to the lower substrate 100 may transmit energies thereof to the load through the interconnection structure. The electrons, after losing their energies by transmitting their energies to the load, may be transferred to the conductive layer 154 through the interconnection structure. The electrons transferred to the conductive layer 154 may pass through the catalytic layer 152 and the electrolyte 140 to return to the dye layer 130 again. Thus, the dye-sensitized solar cell may continually generate electrical current through the above electron circulation system. According to an embodiment of the present invention, the dye-sensitized solar cell having the increased energy conversion efficiency and useful life may be provided.

FIG. 2 is a sectional view of a dye-sensitized solar cell according to another embodiment of the preset invention.

Referring to FIG. 2, a lower substrate 102 is prepared. An upper substrate 151 spaced from the lower substrate 102 may be disposed. The upper substrate 151 may have a light emitting surface facing a surface of the lower substrate 102 and a light incident surface opposite to the light emitting surface. A dielectric 110 may be disposed on the surface of the lower substrate 102. Thus, the dielectric 110 may be disposed between the lower substrate 102 and the upper substrate 151. A semiconductor electrode layer 125 including electrode dots 120 may be disposed on the dielectric 110. Dye layer 130 may be disposed on surfaces of the electrode dots 120. An electrolyte 140 may be disposed between the lower substrate 102 and the upper substrate 151. As described above, since the dielectric 110 is disposed on the surface of the lower substrate 102, the electrolyte 140 may be disposed between the dielectric 110 and the upper substrate 151.

The lower substrate 102 may be flexible. For example, the lower substrate 102 may include one of a polymer layer coated with a conductive material or a metal layer. The conductive material coated on the polymer layer may include ITO, FTO, and ATO. The polymer layer may be formed of one of polyethylene terephthalate (PET), polycarbonate, polyimide and polyethylenenaphthalate. The metal layer may include a sufficiently thin metal film such that it is flexible.

The upper substrate 151 may be flexible. For example, the upper substrate 151 may include a transparent polymer layer. The transparent polymer layer may be formed of PET, polycarbonate, polyimide and polyethylenenaphthalate.

A catalytic layer 152 may be disposed on the light emitting surface of the upper substrate 151. A conductive layer 154 may be disposed between the catalytic layer 152 and the light emitting surface. Thus, the conductive layer 154 and the catalytic layer 152 may be sequentially disposed on the light emitting surface of the upper substrate 151. The conductive layer 154 and the catalytic layer 152 may be disposed in the same manner as described in FIG. 1. The upper substrate 151, the conductive layer 154, and the catalytic layer 152 may constitute an upper substrate structure 156.

The dielectric 110, the semiconductor electrode layer 125 including electrode dots 120, and the electrolyte 140 may be disposed in the same manner as described in FIG. 1.

Thus, since the lower substrate 102 and the upper substrate 151 are flexible, the dye-sensitized solar cell may be flexible. In addition, since the dielectric 110 is disposed on the surface of the lower substrate 102, the premature recombination of electrons and the corrosion of the lower substrate 102 may be minimized Therefore, the flexible dye-sensitized solar cell having increased energy conversion efficiency and useful life may be provided.

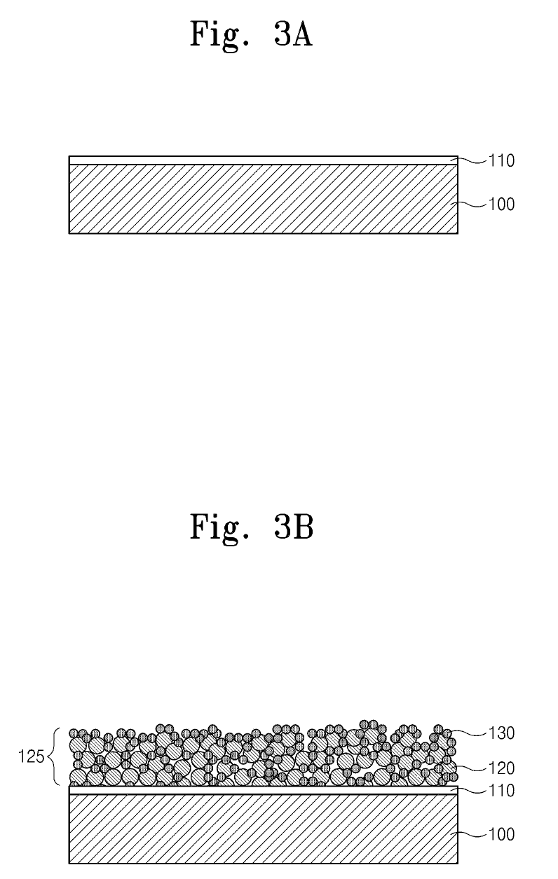

FIGS. 3A and 3B are sectional views illustrating a method of fabricating a dye-sensitized solar cell according to an embodiment of the present invention.

Referring to FIG. 3A, a dielectric 110 may be formed on a lower substrate 100. The dielectric 110 may be formed using one of a spin-coating, a dip-coating, a chemical vapour deposition, a physical vapour deposition, and an atomic layer chemical vapor deposition. The dielectric 110 may include one of a silicon oxide layer and a ceramic or polymer layer. For example, the dielectric 110 may include a silicon oxide layer formed by one of the spin-coating and the dip-coating using one of tetraethyl orthosilicate (TEOS), tetramethyl orthosilicate (TMOS), tetrapropyl orthosilicate (TPOS), and tetrabutyl orthosilicate (TB OS) as a precursor. In case where the dielectric 110 is formed using the spin-coating or the dip-coating, fabrication costs of the dielectric 110 may be relatively inexpensive when compared to the dielectric 110 formed using the vapor deposition. Also, a process of forming the dielectric 110 may be relatively simple than that of the dielectric 110 formed using the vapor deposition. The dielectric 110 may have a thickness in the range of several nanometers to several hundred manometers.

After the dielectric 110 is formed, a thermal process may be further performed. For example, when the dielectric 110 is formed by one of the spin-coating and the dip-coating using one of TEOS, TMOS, TPOS, and TBOS as a precursor, a thermal process may be further performed after the dielectric 110 is formed.

Referring to FIG. 3B, a semiconductor electrode layer 125 including electrode dots 120 may be disposed on the dielectric 110. The electrode dots 120 may include titanium oxide particles having a size ranging from about 3 nm to about 30 nm The semiconductor electrode layer 125 including the electrode dots 120 may be coated at a thickness ranging from about 5 mm to about 30 mm on the lower substrate 100. Here, a process of forming the semiconductor electrode layer 125 may include coating a viscous colloid having TiO₂ nanoparticles on the lower substrate 100, and performing a predetermined thermal process on the coated viscous colloid to leave only the TiO₂ nanoparticles on the lower substrate 100. Specifically, the preparation of the viscous colloid having the TiO₂ nanoparticles may include preparing a liquefied TiO₂ colloid, evaporating a solvent from the liquefied TiO₂ colloid, and adding at least one of polyethylenglycol and polyethyleneoxide. Here, the liquefied TiO₂ colloid may be prepared by adding titanium isopropoxide and acetic acid to an autoclave maintained at 220° C. and carrying out hydrothermal synthesis. Also, the evaporating of the solvent is performed until the proportion of TiO₂ became about 10% to about 12% by weight. The TiO₂ nanoparticles constituting the electrode dots 120 are created in the liquefied TiO₂ colloid through the above-described processes. The polyethylenglycol or polyethyleneoxide may be added to allow the colloidal solution containing the TiO₂ nanoparticles to obtain the appropriate viscosity. The added polyethylenglycol or polyethyleneoxide may be removed through the thermal process. The thermal process may be performed at a temperature between about 450° C. to about 550° C. As a result, only the TiO₂ nanoparticles may remain on the lower substrate 100.

A dye layer 130 may be absorbed on surfaces of the electrode dots 120. The forming of the dye layer 130 may include immersing the lower substrate 100 including the semiconductor electrode layer 125 into an alcohol solution including dye for about 24 hours. Then, the lower substrate 100 may be drawn from the alcohol solution. Thereafter, cleaning the lower substrate 100 with alcohol may be further performed. The dye may include a ruthenium complex. For example, the dye may include N719 (Ru(dcbpy)2(NCS)2 containing 2 protons). Alternatively, at least one of various well-known dye materials such as N712, Z907, Z910, and K19 may be used for fabricating the dye-sensitized solar cell according to the present invention.

A method of fabricating a dye-sensitized solar cell according to an embodiment of the present invention will subsequently described with reference again to FIG. 1.

Referring to FIG. 1, an upper substrate 150 may be disposed on the semiconductor electrode layer 125. The upper substrate 150 may have a light emitting surface facing a surface of the lower substrate 100 and a light incident surface opposite to the light emitting surface. A conductive layer 154 may be formed on the light emitting surface of the upper substrate 150. A catalytic layer 152 may be formed on the conductive layer 154. Thus, the conductive layer 154 may be disposed between the light emitting surface of the upper substrate 150 and the catalytic layer 152. The upper substrate 150, the conductive layer 154, and the catalytic layer 152 may constitute an upper substrate structure 156.

The upper substrate 150 may include a glass substrate. The conductive layer 154 may be formed of at least one of ITO, SnO₂, FTO, ZnO, and carbon nanotubes. The catalyst layer 152 may include a Pt layer deposited on the conductive layer 154 at a thickness ranging from about 5-10 μg/cm².

The upper substrate structure 156 may be attached to the lower substrate 100. This attaching process may include forming a polymer layer (not shown) between the lower substrate 100 and the upper substrate structure 156, and compressing the lower substrate 100 and the upper substrate structure 156 at a temperature ranging from about 100° C. to about 140° C. at about 1 to about 3 bar of pressure. Here, the polymer layer may employ the product called SURLYN manufactured by the company, DuPont.

An electrolyte 140 may be injected between the lower substrate 100 and the upper substrate structure 156. The electrolyte 140 may include a redox iodide electrolyte. For example, the electrolyte 140 may include an acetonitrile electrolyte containing 0.6 M butylmethylimidazolium, 0.02 M I₂, 0.1 M guanidinium thiocyanate, and 0.5 M 4-tert-butylpyridine. Also, the electrolyte 140 may include alkylimidazolium iodides or tetra-alkyl ammoniumiodides. The electrolyte 140 may further include tert-butylpyridin (TBP), benzimidazole (BI), and N-Methylbenzimidazole (NMBI) as surface additives, and acetonitrile, propionitrile, or a mixed solution of acetonitrile and valeronitrile may be used as a solvent.

Thus, the method of fabricating the dye-sensitized solar cell in which the dielectric 110 is formed on the surface of the lower substrate 100 will be provided.

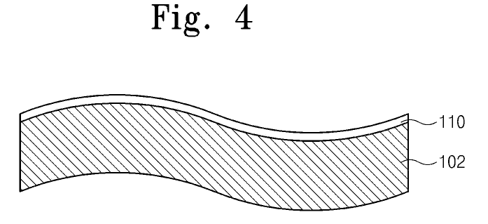

FIG. 4 is a sectional view illustrating a method of fabricating a dye-sensitized solar cell according to another embodiment of the present invention.

Referring to FIG. 4, a flexible lower substrate 102 is prepared. The lower substrate 102 may include one of a polymer layer coated with a conductive material or a metal layer. The conductive material coated on the polymer layer may include ITO, FTO, and ATO. The polymer layer may be formed of one of PET, polycarbonate, polyimide and polyethylenenaphthalate. The metal layer may include a sufficiently thin metal film such that it is flexible.

A dielectric 110 may be disposed on the lower substrate 102. The dielectric 110 may be formed using the above-described method.

A method of fabricating a dye-sensitized solar cell according to another embodiment of the present invention will subsequently described with reference again to FIG. 2.

Referring to FIG. 2, according to the above-described method, a semiconductor electrode layer 125 including electrode dots 120 may be formed on the dielectric 110. A dye layer 130 may be absorbed on surfaces of the electrode dots 120.

An upper substrate 151 may be disposed on the semiconductor electrode layer 125. The upper substrate 151 may be flexible. The upper substrate 151 may include a transparent polymer layer. For example, the upper substrate 151 may be formed of PET, polycarbonate, polyimide and polyethylenenaphthalate. A conductive layer 154 and a catalyst layer 152 may be formed on the upper substrate 151 using the above-described method. The upper substrate 151, the conductive layer 154, and the catalyst layer 152 may constitute an upper substrate structure 157.

Thereafter, according to the above-described method, the upper substrate structure 157 and the lower substrate 102 may be attached, and an electrolyte 140 may be injected between the lower substrate 102 and the upper substrate structure 157.

Thus, the method of fabricating the flexible dye-sensitized solar cell in which the dielectric 110 is formed on the surface of the lower substrate 102 will be provided.

According to the embodiments of the present invention, the dielectric may be disposed between the lower substrate and the electrolyte. Thus, the premature recombination may be minimized, and the dye-sensitized solar cell having the increased energy conversion efficiency may be provided.

Also, the lower substrate may be separated from the electrolyte by the dielectric. Therefore, the corrosion of the lower substrate due to the electrolyte may be minimized, and thus, the dye-sensitized solar cell having the increased useful life may be provided.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A dye-sensitized solar cell, comprising:
a lower substrate;
an upper substrate spaced from the lower substrate, the upper substrate having a light emitting surface facing a surface of the lower substrate and a light incident surface opposite to the light emitting surface;
a dielectric disposed on the surface of the lower substrate;
a semiconductor electrode layer comprising electrode dots disposed on the dielectric;
a dye layer disposed on surfaces of the electrode dots; and
an electrolyte disposed between the lower substrate and the upper substrate.

2. The dye-sensitized solar cell of claim 1, wherein the dielectric comprises a silicon oxide layer or is formed of a ceramic or polymer material.

3. The dye-sensitized solar cell of claim 1, wherein the lower and upper substrates are flexible.

4. The dye-sensitized solar cell of claim 3, wherein the lower substrate comprises one of a polymer layer coated with a conductive material or a metal layer.

5. The dye-sensitized solar cell of claim 4, wherein the upper substrate comprises a transparent polymer layer.

6. The dye-sensitized solar cell of claim 1, further comprising:
a catalyst layer disposed on the light emitting surface of the upper substrate; and
a conductive layer disposed between the catalyst layer and the light emitting surface.

7. The dye-sensitized solar cell of claim 1, wherein the lower substrate is formed of at least one of metals and metal alloys or comprises a glass or a polymer layer coated with a conductive material.

8. A method of fabricating a dye-sensitized solar cell, the method comprising:
forming a dielectric on a lower substrate;
forming a semiconductor electrode layer comprising electrode dots on the dielectric;
absorbing a dye layer on surfaces of the electrode dots;
disposing an upper substrate on the semiconductor electrode layer; and
injecting an electrolyte between the lower substrate and the upper substrate.

9. The method of claim 8, wherein the dielectric is formed using one of a spin-coating, a dip-coating, a chemical vapour deposition, a physical vapour deposition, and an atomic layer chemical vapor deposition.

10. The method of claim 9, further comprising performing a thermal process after the dielectric is formed.
